(19) United States
(12) Patent Application Publication
(10) Pub. No.: US 2024/0162375 A1
(43) Pub. Date: May 16, 2024

(54) LIGHT-EMITTING DEVICE

(71) Applicant: EPISTAR CORPORATION, Hsinchu (TW)

(72) Inventors: Heng-Ying CHO, Hsinchu (TW); Yong-Yang CHEN, Hsinchu (TW); Yu-Ling LIN, Hsinchu (TW); Wei-Chen TSAO, Hsinchu (TW)

(21) Appl. No.: 18/498,722

(22) Filed: Oct. 31, 2023

(30) Foreign Application Priority Data
Nov. 16, 2022 (TW) 111143777

(51) Int. Cl. H01L 33/10; H01L 33/36

(52) U.S. Cl. CPC H01L 33/10; H01L 33/36

(57) ABSTRACT

A light-emitting device comprises a first semiconductor layer and a semiconductor mesa formed on the first semiconductor layer, wherein the first semiconductor layer comprises a first sidewall and a first semiconductor layer first surface surrounding the semiconductor mesa, and the semiconductor mesa comprises a second sidewall; and a first reflective structure comprising a first reflective portion covering the first sidewall and a second reflective portion covering the second sidewall, wherein the first reflective portion and the second reflective portion are connected to form a first reflective structure outer opening to expose the first semiconductor layer first surface in a top view of the light-emitting device.

### REFERENCE TO RELATED APPLICATION

This application claims the right of priority based on TW Application Serial No. 111143777, filed on Nov. 16, 2022, and the content of which is hereby incorporated by reference in its entirety.

### TECHNICAL FIELD

The application relates to a light-emitting device, and more particularly, to a flip chip type light-emitting device including a plurality of electrode contact areas.

### DESCRIPTION OF BACKGROUND ART

Light-Emitting Diode (LED) is a solid-state semiconductor light-emitting device, which has the advantages of low power consumption, low heat generation, long working lifetime, shockproof, small volume, fast reaction speed, and good photoelectric property, such as stable emission wavelength. Therefore, the light-emitting diodes are widely used in the household appliances, the equipment indicators, and the optoelectronic products.

### SUMMARY OF THE APPLICATION

A light-emitting device comprises a first semiconductor layer and a semiconductor mesa formed on the first semiconductor layer, wherein the first semiconductor layer comprises a first sidewall and a first semiconductor layer first surface surrounding the semiconductor mesa, and the semiconductor mesa comprises a second sidewall; a first reflective structure comprising a first reflective portion covering the first sidewall and a second reflective portion covering the second sidewall, wherein the first reflective portion and the second reflective portion are connected to form a first reflective structure outer opening to expose the first semiconductor layer first surface in a top view of the light-emitting device; a metal reflective layer comprising an edge formed on the semiconductor mesa and covered by the first reflective structure; a first extending electrode covering the first reflective structure and contacting the first semiconductor layer first surface through the first reflective structure outer opening; and a second reflective structure covering the first extending electrode and contacting the first reflective portion of the first reflective structure, wherein the first extending electrode comprises a first extending electrode protrusion protruding outwards the edge of the metal reflective layer, the first extending electrode protrusion comprises a first region between the first reflective structure and the second reflective structure and a second region directly contacts the first semiconductor layer first surface, and the first region comprises a first extending electrode first width W1 larger than a first extending electrode second width W2 of the second region, and the first reflective structure formed under the first extending electrode comprises a first reflective structure thickness D1, the second reflective structure formed above the first extending electrode comprises a second reflective structure first thickness D2, and the first reflective structure thickness D1 is smaller than the second reflective structure first thickness D2.

### BRIEF DESCRIPTION OF THE DRAWINGS

FIG. 1 illustrates a top view of a light-emitting device 1 in accordance with an embodiment of the present application;

FIG. 2 illustrates a cross-sectional view of the light-emitting device 1 taken along the line X-X′ in FIG. 1;

FIG. 3 illustrates an enlarged view of the area I indicated by the dotted line in FIG. 1;

FIG. 4A illustrates a cross-sectional view of the light-emitting device 1 taken along the line L-L′ in FIG. 3;

FIG. 4B illustrates an enlarged view of the area indicated by the dotted line in FIG. 4A;

FIG. 4C illustrates a cross-sectional view of the light-emitting device 1 taken along the line L-L′ in FIG. 3 in accordance with another embodiment of the present application;

FIG. 5 illustrates a cross-sectional view of the light-emitting device 1 taken along the line Y-Y′ in FIG. 1;

FIG. 6 illustrates a schematic diagram of a light-emitting apparatus 2 in accordance with an embodiment of the present application; and

FIG. 7 illustrates a schematic diagram of a light-emitting apparatus 3 in accordance with an embodiment of the present application.

### DETAILED DESCRIPTION OF PREFERRED EMBODIMENTS

The embodiment of the application is illustrated in detail, and is plotted in the drawings. The same or the similar part is illustrated in the drawings and the specification with the same number.

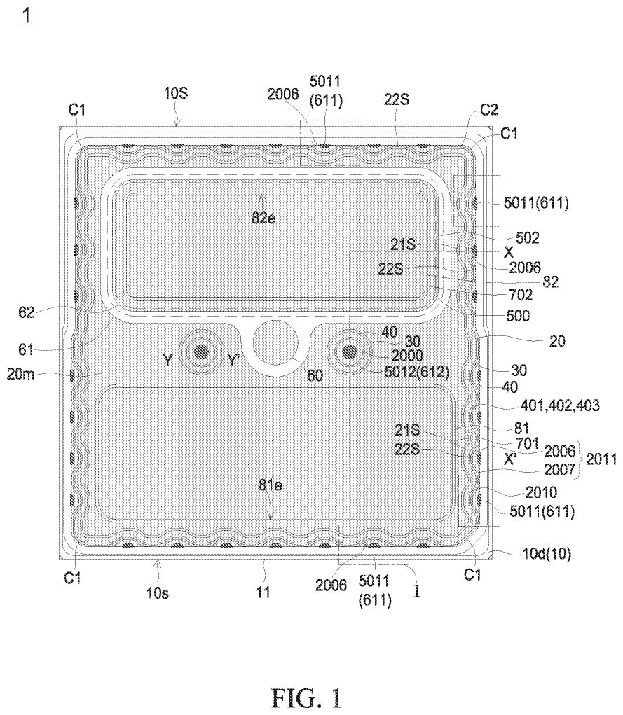

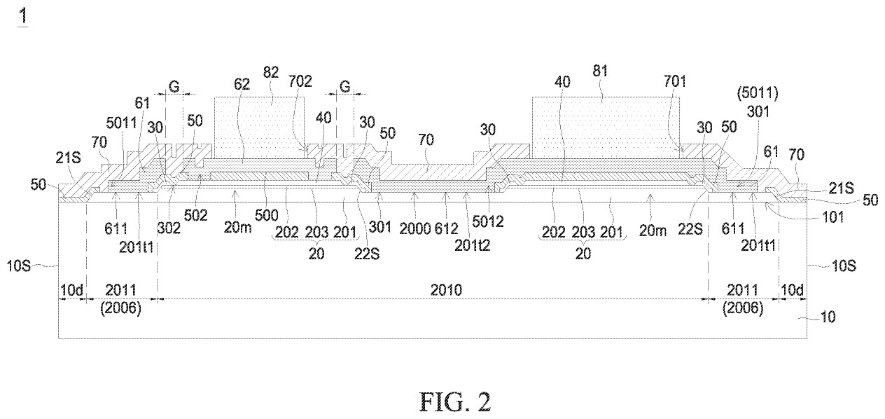

FIG. 1 illustrates a top view of a light-emitting device 1 in accordance with an embodiment of the present application. FIG. 2 illustrates a cross-sectional view taken along the line X-X′ in FIG. 1.

As shown in FIGS. 1 and 2, the light-emitting device 1 comprises a substrate 10 and a semiconductor stack 20 formed on an upper surface 101 of the substrate 10. The semiconductor stack 20 comprises a first semiconductor layer 201 and a semiconductor mesa 20m formed on the first semiconductor layer 201. The semiconductor mesa 20m comprises a second semiconductor layer 202 and an active layer 203. In a top view and a side view of the light-emitting device 1, the semiconductor stack 20 comprises an outer region 2011 and an inner region 2010. The first semiconductor layer 201 formed in the outer region 2011 comprises a first semiconductor layer first surface 201t1, and the first semiconductor layer 201 formed in the inner region 2010 comprises a first semiconductor layer second surface 201t2. The semiconductor mesa 20m is completely or partially surrounded by the first semiconductor layer first surface 201t1 of the first semiconductor layer 201 exposed in the outer region 2011. A first reflective structure 50 comprises one or a plurality of first reflective structure outer openings 5011 formed in the outer region 2011, one or a plurality of first reflective structure inner openings 5012 formed in the inner region 2010, and one or a plurality of first reflective structure second openings 502 formed on the semiconductor mesa 20m in the inner region 2010. A first extending electrode 61 completely or partially covers the first reflective structure outer opening 5011, and contacts the first semiconductor layer first surface 201t1 in the outer region 2011 through the first reflective structure outer opening 5011 to form one or a plurality of first extending electrode first contact areas 611. The first extending electrode 61 completely or partially covers the first reflective structure inner opening 5012, and contacts the first semiconductor layer second surface 201t2 in the inner region 2010 through the first reflective structure inner opening 5012 to form one or a plurality of first extending electrode second contact areas 612. A second extending electrode 62 covers the first reflective structure second opening 502 and is electrically connected to the second semiconductor layer 202 through the first reflective structure second opening 502. A second reflective structure 70 covers the first reflective structure 50, the first extending electrode 61, and the second extending electrode 62.

The substrate 10 may be a growth substrate for epitaxially growing the semiconductor stack 20. The substrate 10 comprises a gallium arsenide (GaAs) wafer for the epitaxial growth of aluminum gallium indium phosphide (AlGaInP), or a sapphire (Al₂O₃) wafer, a gallium nitride (GaN) wafer, a silicon carbide (SiC) wafer, or an aluminum nitride (AlN) wafer for the epitaxial growth of gallium nitride (GaN), indium gallium nitride (InGaN), or aluminum gallium nitride (AlGaN).

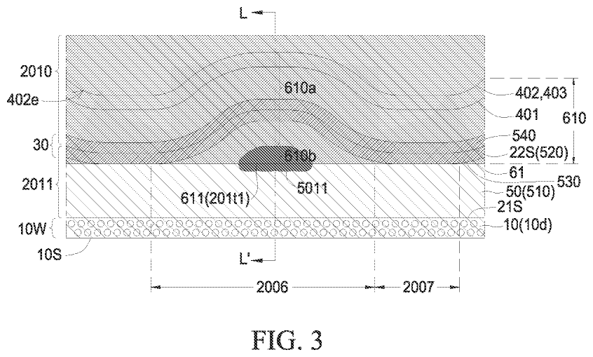

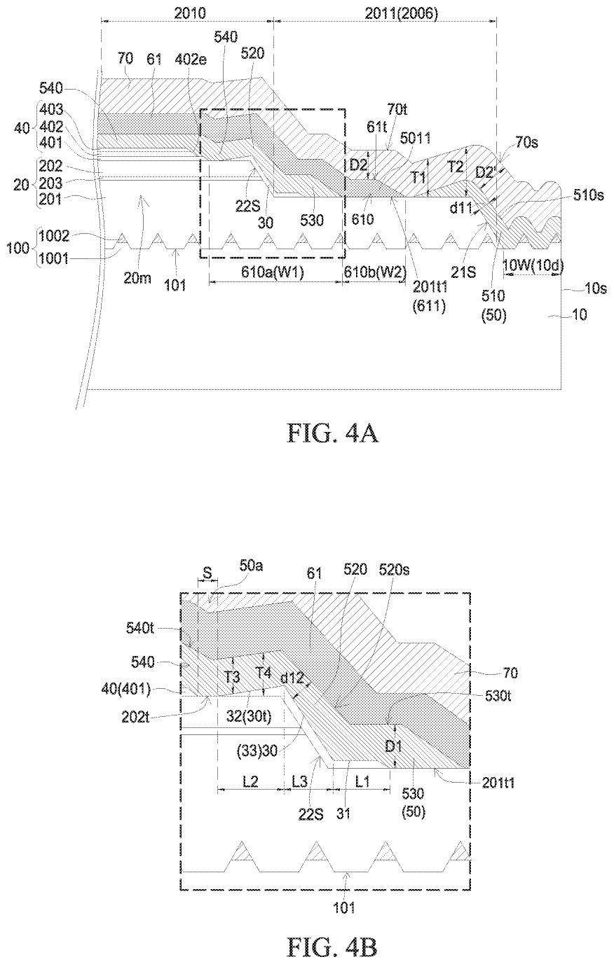

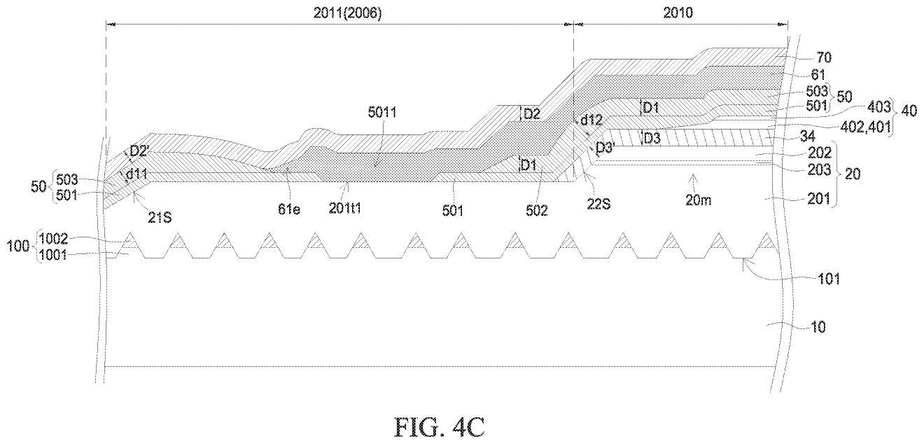

FIG. 3 illustrates an enlarged view of the area I indicated by the dotted line in FIG. 1. FIG. 4A illustrates a cross-sectional view taken along the line L-L′ in FIG. 3. A surface of the substrate 10 in contact with the semiconductor stack 20 can be a roughened surface to improve the epitaxial quality of the semiconductor stack 20 and increase the light extraction efficiency of the light-emitting device 1. The roughened surface comprises a surface with an irregular morphology or a surface with a regular morphology. For example, with respect to the upper surface 101 of the substrate 10, the substrate 10 comprises one or a plurality of convex portions 100 protruding from the upper surface 101, or comprises one or a plurality of concave portions (not shown) recessed in the upper surface 101. In the cross-sectional view, the convex portion 100 or the concave portion (not shown) comprises a semicircular shape or a polygonal shape.

In an embodiment of the application, in order to increase the light extraction efficiency of the light-emitting device 1, the plurality of convex portions 100 comprise a first layer 1001 and a second layer 1002. The first layer 1001 comprises the same material as the substrate 10, such as gallium arsenide (GaAs), sapphire (Al₂O₃), gallium nitride (GaN), silicon carbide (SiC), or aluminum nitride (AN). The second layer 1002 comprises a material different from that of the first layer 1001 and that of the substrate 10. The material of the second layer 1002 comprises an insulating material, such as silicon oxide, silicon nitride, or silicon oxynitride. The refractive index of the material of the second layer 1002 is lower than that of the substrate 10, which increases the light extraction efficiency of the light-emitting device 1. In the side view of the light-emitting device 1, the convex portion 100 comprises a hemispherical shape, a cannonball shape, or a cone shape. The topmost end of the convex portion 100 can be a curved surface or a sharp point. In an embodiment of the present application, the convex portion 100 only comprises the second layer 1002 and lacks the first layer 1001, wherein a bottom surface of the second layer 1002 is flush with the upper surface 101 of the substrate 10. In an embodiment of the present application, the convex portions 100 formed on a dicing street 10d comprises a size or a shape that is different from those of the convex portions 100 formed under the semiconductor stack 20. For example, the second layer 1002 of the convex portion 100 on the dicing street 10d comprises a thickness that is smaller than the thickness of the second layer 1002 of the convex portion 100 formed under the semiconductor stack 20.

In an embodiment of the present application, the metal organic chemical vapor deposition (MOCVD), molecular beam epitaxy (MBE), hydride vapor phase (HVPE), physical vapor deposition (PVD), or the ion plating method is provided to form the semiconductor stack 20 with photoelectrical characteristics on the substrate 10, such as a light-emitting stack. The physical vapor deposition method comprises sputtering or evaporation.

The wavelength of the light emitted from the light-emitting device 1 is adjusted by changing the physical and the chemical composition of one or more layers in the semiconductor stack 20. The material of the semiconductor stack 20 comprises III-V group semiconductor materials, such as AlₓIn_{y}Ga_{(1-x-y)}N or AlₓIn_{y}Ga_{(1-x-y)}P, where 0≤x, y≤1; (x+y)≤1. When the material of the semiconductor stack 20 comprises AlInGaP series material, the red light having a wavelength between 610 nm and 650 nm can be emitted. When the material of the semiconductor stack 20 comprises InGaN series material, the blue light having a wavelength between 400 nm and 490 nm or the green light having a wavelength between 530 nm and 570 nm can be emitted. When the material of the semiconductor stack 20 comprises AlGaN series material or AlInGaN series material, the ultraviolet light having a wavelength between 250 nm and 400 nm can be emitted.

The first semiconductor layer 201 and the second semiconductor layer 202 can be cladding layers or confinement layers having different conductivity types, electrical properties, polarities, or doping elements for providing the electrons or the holes. For example, the first semiconductor layer 201 is an n-type semiconductor and the second semiconductor layer 202 is a p-type semiconductor. The active layer 203 is formed between the first semiconductor layer 201 and the second semiconductor layer 202. The electrons and the holes combined in the active layer 203 under a current driving to convert the electrical energy into the light energy and then the light is emitted from the active layer 203. The active layer 203 can be a single heterostructure (SH), a double heterostructure (DH), a double-side double heterostructure (DDH), or a multi-quantum well structure (MQW). The material of the active layer 203 can be an i-type, p-type or n-type semiconductor. The first semiconductor layer 201, the second semiconductor layer 202, or the active layer 203 can be a single layer or a structure comprising a plurality of sub-layers.

In an embodiment of the present application, the semiconductor stack 20 further comprise a buffer layer (not shown) formed between the first semiconductor layer 201 and the substrate 10 which can release the stress caused by the lattice mismatch between the materials of the substrate 10 and the semiconductor stack 20 so the lattice dislocation and the lattice defect are reduced and the epitaxial quality of the semiconductor stack 20 is improved. The buffer layer comprises a single layer or a structure comprising a plurality of sub-layers. In an embodiment, an aluminum nitride (AlN) layer formed by PVD method can be the buffer layer located between the semiconductor stack 20 and the substrate 10 to improve the epitaxial quality of the semiconductor stack 20. In an embodiment, when the method for forming aluminum nitride (AlN) is PVD, the target can be made of aluminum nitride. In another embodiment, a target made of aluminum reacts with a nitrogen source to form the aluminum nitride.

In an embodiment of the present application, as shown in FIGS. 1 and 2, the light-emitting device 1 comprises a first electrode pad 81 and a second electrode pad 82 formed on the semiconductor mesa 20m, and comprises a flip chip structure.

As shown in FIG. 1, from the top view of the light-emitting device 1, the semiconductor stack 20 is substantially rectangular in the top view. The first semiconductor layer 201 comprises four first corners C1 and four first sidewalls 21S. The semiconductor mesa 20m comprises four second corners C2 and four second sidewalls 22S. The first sidewall 21S and the second sidewall 22S comprise straight lines, square corrugations, wavy patterns, or a combination of any two of the above. The first corner C1 and the second corner C2 comprise arcs, straight lines, or a combination of the above.

As shown in FIG. 4A, the light-emitting device 1 comprises the dicing street 10d that exposes the upper surface 101 of the substrate 10 and is formed between a side 10S of the substrate 10 and the first sidewall 21S of the first semiconductor layer 201, and is formed on a periphery of the light-emitting device 1 to surround the semiconductor stack 20. The dicing street 10d comprises a width 10W between 1 μm and 50 μm, between 5 μm and 30 μm, or between 5 μm and 15 μkm.

In the embodiment, the semiconductor stack 20 is patterned by the etching process, a part of the second semiconductor layer 202 and the active layer 203 is removed to expose the first semiconductor layer 201 and form the outer region 2011 and the inner region 2010 surrounded by the outer region 2011. The inner region 2010 comprises one or a plurality of semiconductor mesas 20m formed on the first semiconductor layer 201, and one or a plurality of vias 2000 exposing the first semiconductor layer second surface 201t2. In an embodiment, the plurality of semiconductor mesas 20m can be separated from each other in the side view or the top view of the light-emitting device 1. From the top view of the light-emitting device 1, as shown in FIGS. 1, 3 and 4A, the outer region 2011 comprises a plurality of recessed portions 2006, and two adjacent recessed portions 2006 are separated by a protruding portion 2007. The recessed portion 2006 is not provided with the second semiconductor layer 202 and the active layer 203, and the recessed portion 2006 exposes the first semiconductor layer first surface 201t1. The protruding portion 2007 comprises the first semiconductor layer 201, the active layer 203, and the second semiconductor layer 202. Compared with the recessed portion 2006, a top view shape of the protruding portion 2007 comprises an arc or a rectangle. The recessed portion 2006 exposes the first semiconductor layer first surface 201t1, so that the first semiconductor layer first surface 201t1 is formed between the first sidewall 21S of the first semiconductor layer 201 and the second sidewall 22S of the semiconductor mesa 20m, and each of the first sidewall 21S and the second sidewall 22S is connected to the first semiconductor layer first surface 201t1 with an inclined angle. The second sidewall 22S of the protruding portion 2007 is closer to the side 10S of the substrate 10 than the second sidewall 22S of the recessed portion 2006 to the side 10S of the substrate 10 to retain more light-emitting area of the active layer 203, and the second sidewall 22S is covered by the first reflective structure 50. In the embodiment, the first reflective structure outer opening 5011 comprising a semicircle shape is formed in the recessed portion 2006. The top view shape of the first reflective structure outer openings 5011 comprises a semicircle, a triangle, a trapezoid, or a rectangle. The size and the shape of the first reflective structure outer opening 5011 is not limited thereto. In addition, the first reflective structure outer openings 5011 with different sizes or shapes therebetween can also be provided.

In the top view or the side view of the light-emitting device 1, as shown in FIGS. 1 and 2, the plurality of vias 2000 are formed in the inner region 2010, and are arranged in a straight line or an array at a fixed distance from each other. Each via 2000 comprises a width between 5 μm and 20 μm, or between 8 μm and 15 μm. The top view shape of the via 2000 comprises a circle, an ellipse, a semicircle, a rectangle, or a long strip. In the embodiment, the first semiconductor layer second surface 201t2 formed on the via 2000 is continuously surrounded by the second sidewall 22S.

As shown in FIG. 2, the first extending electrode 61 contacts the first semiconductor layer second surface 201t2 through the plurality of vias 2000 formed in the inner region 2010 and contacts the first semiconductor layer first surface 201t2 through the recessed portion 2006 formed in the outer region 2011 to electrically connected to the first semiconductor layer 201. The second extending electrode 62 is formed on the second semiconductor layer 202 of the semiconductor mesa 20m and is electrically connected to the second semiconductor layer 202 through a contact electrode 40.

As shown in FIG. 2, an insulating layer 30 covers the second sidewall 22S of the semiconductor mesa 20m, comprises a first insulating layer opening 301 formed on the via 2000 and/or formed on the recessed portion 2006 to expose the first semiconductor layer 201, and a second insulating layer opening 302 formed on the semiconductor mesa 20m to expose the second semiconductor layer 202. The insulating layer 30 formed on the via 2000 (not shown) or on the recessed portion 2006 (as shown in FIG. 4B) comprises a first insulating layer portion 31 contacting the first semiconductor layer 201, a second insulating layer portion 32 contacting the second semiconductor layer 202, and a third insulating layer portion 33 covering the second sidewall 22S. The first insulating layer portion 31 comprises a first length L1 between 5 μm and 10 μm. The second insulating layer portion 32 comprises a second length L2 between 13 μm and 16 μm. The third insulating layer portion 33 comprises a third length L3 respectively shorter than the first length L1 and the second length L2. In an embodiment, the second length L2 is longer than the first length L1.

The contact electrode 40 is formed on the second insulating layer opening 302 and contacts the second semiconductor layer 202. The contact electrode 40 substantially covers all of the upper surface of the semiconductor mesa 20m. For example, the contact electrode 40 covers more than 80% area of the semiconductor mesa 20m or more than 90%.

In an embodiment of the present application, as shown in FIG. 4A, the contact electrode 40 comprises one layer or multiple layers selected from a group including a transparent conductive layer 401, a metal reflective layer 402, and a barrier layer 403. In an embodiment, the transparent conductive layer 401 can be disposed between the metal reflective layer 402 and the second semiconductor layer 202, and the metal reflective layer 402 can be disposed between the transparent conductive layer 401 and the barrier layer 403. In order to reduce the contact resistance and improve the current diffusion efficiency, the transparent conductive layer 401 comprises a material that is transparent to the light emitted from the active layer 203, such as a transparent conductive oxide. The transparent conductive oxide comprises indium tin oxide (ITO) or indium zinc oxide (IZO). In an embodiment of the present application, the transparent conductive layer 401 can be a metal layer with a thickness less than 500 angstroms.

The material of the metal reflective layer 402 comprises reflective metals, such as aluminum (Al), silver (Ag), rhodium (Rh), platinum (Pt), or an alloy of the above materials. The metal reflective layer 402 is provided to reflect the light emitted from the active layer 203 and direct the reflected light toward the substrate 10 to be emitted outwards.

In an embodiment, the barrier layer 403 covers one side of the metal reflective layer 402 to prevent the metal reflective layer 402 from being oxidized and deteriorating its reflectivity. The material of the barrier layer 403 comprises metal materials, such as titanium (Ti), tungsten (W), aluminum (Al), indium (In), tin (Sn), nickel (Ni), chromium (Cr), platinum (Pt), or an alloy of the above materials. In the embodiment, as shown in FIG. 4A, the barrier layer 403 does not totally cover the metal reflective layer 402, and one side of the barrier layer 403 can be flush with one side of the metal reflective layer 402 or formed within the one side of the metal reflective layer 402 to expose a portion of the upper surface of the metal reflective layer 402. In an embodiment, the metal reflective layer 402 comprises a tail portion not covered by the barrier layer 403, and the tail portion comprises a thickness gradually decreases toward the second side 22S.

The transparent conductive layer 401 spreads the current injected from the metal reflective layer 402 to prevent the current from being concentrated in a local area of the second semiconductor layer 202. The transparent conductive layer 401 is spaced apart from the edge of the semiconductor mesa 20m with a distance, thereby preventing the light absorbed by the transparent conductive layer 401 at the edge of the semiconductor mesa 20m. In an embodiment, the distance between the edge of the transparent conductive layer 401 and the edge of the semiconductor mesa 20m can be more than 2 μm, 4 μm, or 6 μm, but less than 15 μm in view of the current distribution.

The contact electrode 40 spreads the current supplied through the second extending electrode 62 onto the second semiconductor layer 202. In addition, the contact electrode 40 further comprises the reflectivity to be provided as a layer reflecting the light emitted from the light-emitting device 1 toward the light extraction surface, i.e., one side of the substrate 10.

In an embodiment of the application, as shown in FIG. 4B, the contact electrode 40 does not contact the insulating layer 30, and a space S is located between the insulating layer 30 and the contact electrode 40. A portion of the first reflective structure 50 is located within the space S between the contact electrode 40 and the insulating layer 30, so that the first reflective structure 50 comprises a recess 50a corresponding to the space S.

In another embodiment of the application (not shown), the contact electrode 40 comprises a first contact portion covering the second insulating layer portion 32 of the insulating layer 30 and a second contact portion directly contacting the second semiconductor layer 202. The first contact portion of the contact electrode 40 comprises a thickness smaller than that of the second contact portion, and the thickness of the first contact portion gradually decreases from the inside of the semiconductor mesa 20m toward the second sidewall 22S. The thickness is measured in a direction perpendicular to the upper surface of the second semiconductor layer 202.

As shown in FIGS. 1 and 2, the first reflective structure 50 comprises one or the plurality of first reflective structure outer openings 5011 formed on the recessed portion 2006 and exposing the first semiconductor layer first surface 201t1, one or the plurality of first reflective structure inner openings 5012 formed on the via 2000 and exposing the first semiconductor layer second surface 201t2, and one or the plurality of first reflective structure second openings 502 formed on the contact electrode 40 and exposing one or more layers of the transparent conductive layer 401, the metal reflective layer 402, and/or the barrier layer 403 of the contact electrode 40. The first reflective structure 50 covers the second sidewall 22S of the second semiconductor layer 202 formed at or adjacent to the outer region 2011, the four first corners C1 of the first semiconductor layer 201, and the first sidewall 21S of the first semiconductor layer 201.

In an embodiment of the application, as shown in FIG. 2, the first reflective structure 50 comprises a first reflective platform 500 formed under the second extending electrode 62 and the second electrode pad 82. In the top view of the light-emitting device 1, as shown in FIG. 1, the first reflective platform 500 is continuously surrounded by one first reflective structure second opening 502, or is discontinuously surrounded by the plurality of first reflective structure second openings 502. The first reflective platform 500 can be formed partially inside or outside a projected area of the second electrode pad 82, so that the first reflective platform 500 comprises a projected area smaller than or larger than the projected area of the second electrode pad 82. In the side view of the light-emitting device 1, the first reflective platform 500 is covered by the second extending electrode 62.

The first extending electrode 61 covers the plurality of first reflective structure outer openings 5011 and the first reflective structure inner opening 5012 of the first reflective structure 50 to contact the first semiconductor layer 201. The second extending electrode 62 covers the first reflective structure second opening 502 to contact the second semiconductor layer 202 and/or the contact electrode 40. In the top view of the light-emitting device 1, the second extending electrode 62 and the first reflective structure second opening 502 comprise the same shape. In an embodiment, the second extending electrode 62 and the first reflective structure second opening 502 comprise approximately the same rectangle shape. In an embodiment, the second extending electrode 62 is larger than the first reflective structure second opening 502, so that the second extending electrode 62 partially covers the first reflective structure 50. The first extending electrode 61 and the second extending electrode 62 are spaced apart with an equal interval or an unequal interval space through the first reflective structure 50. There is a minimum space G between the first extending electrode 61 and the second extending electrode 62 on the semiconductor mesa 20m and that exposes a surface of the first reflective structure 50. The minimum space G is between 3 μm and 30 μm, between 5 μm-25 μm, or between 18 μm-22 μm.

As shown in FIGS. 1 and 2, the first extending electrode 61 covers the first reflective structure inner opening 5012 and contacts the first semiconductor layer 201 through the first reflective structure inner opening 5012 to form the first extending electrode second contact area 612. The first extending electrode 61 covers the first reflective structure outer opening 5011 and contacts the first semiconductor layer 201 in the outer region 2011 through the first reflective structure outer opening 5011 to form the first extending electrode first contact area 611. In the top view of the light-emitting device 1, a plurality of first extending electrode first contact areas 611 is discontinuously formed on the first semiconductor layer 201 and surrounds the semiconductor mesa 20m. The first extending electrode first contact area 611 comprises a first contact area smaller than a second contact area of the first extending electrode second contact area 612. The plurality of first extending electrode first contact areas 611 comprise a first total contact area larger than a second total contact area of the plurality of first extending electrode second contact areas 612.

In the embodiment, the plurality of first extending electrode first contact areas 611 is provided in the outer region 2011 to reduce the total second contact area of the first extending electrode second contact area 612 in the inner region 2010 that can suppress the forward voltage Vf of the light-emitting device 1 and provide a wider light-emitting area.

In the top view of the light-emitting device 1, the plurality of first extending electrode first contact areas 611 is formed in regions other than the four corners (the first corner C1 or the second corner C2), and the plurality of first extending electrode first contact areas 611 is formed with equal or unequal intervals in the outer region 2011 to improve the current density distribution. In the embodiment of the application, the plurality of first extending electrode first contact areas 611 comprises the same or different projected areas.

As shown in FIG. 1, the light-emitting device 1 comprises a pin area 60 formed at the geometric center of the semiconductor stack 20. The pin area 60 is not in contact with the first extending electrode 61 and the second extending electrode 62. In other words, the pin area 60 is electrically isolated from the first extending electrode 61 and the second extending electrode 62, and is not covered by the first electrode pad 81 and the second electrode pad 82. The pin area 60 can protect the epitaxial layers from being damaged by the pin during the subsequent processes, such as die separation or sorting, flipping, die testing, and packaging, wherein the pin is necessary in LED chips sorting and chip bonding process to smoothly detach the LED chips and the blue membrane.

As shown in FIG. 1, the second reflective structure 70 comprises a second reflective structure first opening 701 and a second reflective structure second opening 702 formed on the semiconductor mesa 20m. The first electrode pad 81 and the second electrode pad 82 are respectively adjacent to two opposite sides of the semiconductor stack 20. A side 81e of the first electrode pad 81 is closer to the side 10S of the substrate 10 than a side 82e of the second electrode pad 82 to the side 10S of the substrate 10. As shown in FIG. 2, the first electrode pad 81 covers the second reflective structure first opening 701 to contact the first extending electrode 61, and the second electrode pad 82 covers the second reflective structure second opening 702 to contact the second extending electrode 62, and the first electrode pad 81 and second electrode pad 82 are respectively electrically connected to the first semiconductor layer 201 and the second semiconductor layer 202. The first electrode pad 81 and the second electrode pad 82 comprise different conductivities. For example, the first electrode pad 81 can be an n-type electrode pad, and the second electrode pad 82 can be a p-type electrode pad.

The pin area 60, the first extending electrode 61, the second extending electrode 62, the first electrode pad 81, and the second electrode pad 82 comprise a metal material, such as chromium (Cr), titanium (Ti), and tungsten (W), gold (Au), aluminum (Al), indium (In), tin (Sn), nickel (Ni), platinum (Pt), silver (Ag), or an alloy of the above materials. The pin area 60, the first extending electrode 61, the second extending electrode 62, the first electrode pad 81, and the second electrode pad 82 each comprises a single layer or multiple layers. For example, the pin area 60, the first extending electrode 61, the second extending electrode 62, the first electrode pad 81, or the second electrode pad 82 comprises Ti/Au layers, Ti/Pt/Au layers, Cr/Au layers, Cr/Pt/Au layers, Ni/Au layers, Ni/Pt/Au layers, Cr/Al/Cr/Ni/Au layers, or Ag/NiTi/TiW/Pt layers. The first electrode pad 81 and the second electrode pad 82 can provide an electrical path for an external power source to supply current to the first semiconductor layer 201 and the second semiconductor layer 202. The first extending electrode 61, the second extending electrode 62, the first electrode pad 81, and the second electrode pad 82 each comprises a thickness between 0.2 m and 20 m, between 1.2 m and 10 m, between 1.2 m and m, or between 1.5 m and 6 m.

The insulating layer 30, the first reflective structure 50, and/or the second reflective structure 70 are formed on the semiconductor stack 20 and serve as protective films and antistatic insulating films between layers of the light-emitting device 1. In an embodiment, as the insulating film, the insulating layer 30 comprises a single-layer structure comprising the metal oxide or the metal nitride while the metal can be silicon (Si), titanium (Ti), zirconium (Zr), niobium (Nb), tantalum (Ta), or aluminum (Al), for example. The first reflective structure 50 and the second reflective structure 70 comprise two or more materials with different refractive indices stacked alternately to form a Distributed Bragg Reflector (DBR) structure to selectively reflect the light of a specific wavelength. For example, an insulating reflective structure with high reflectivity can be formed by stacking layers such as SiO₂/TiO₂ or SiO₂/Nb₂O₅. When SiO₂/TiO₂ or SiO₂/Nb₂O₅ forms the Distributed Bragg Reflector (DBR) structure, each layer of the Distributed Bragg Reflector (DBR) structure comprises an optical thickness of one or an integral multiple of a quarter of the wavelength of the light emitted from the active layer 203. The optical thickness of each layer of the Distributed Bragg Reflector (DBR) structure can have a deviation of 30% on the basis of one or an integer multiple of λ/4.

Since the optical thickness of each layer of the Distributed Bragg Reflector (DBR) structure affects the reflectivity thereof and the physical thickness of each layer of the Distributed Bragg Reflector structure is obtained based on the optical thickness, E-beam evaporation can be adopted to form the physical thickness of the first reflective structure 50 and the second reflective structure 70 to stably control the physical thickness of each layer of the first reflective structure 50 and the second reflective structure 70.

In an embodiment of the application, when the first reflective structure 50 comprises the Distributed Bragg Reflector (DBR) structure stacked by SiO₂/TiO₂ or SiO₂/Nb₂O₅, the insulating layer 30 comprises an insulating layer thickness thicker than the thickness of each sub-layer of the first reflective structure 50.

FIG. 4A illustrates a cross-sectional view taken along the line L-L′ in FIG. 3. In a direction parallel to one side of the light-emitting device 1, the protruding portion 2007 comprises a maximum width between 30 μm and 60 μm. The recessed portion 2006 comprises a maximum width between 30 μm and 60 μm. Because the protruding portion 2007 and the recessed portion 2006 comprise substantially complementary shapes, the protruding portion 2007 and the recessed portion 2006 comprise substantially the same width.

As shown in FIGS. 3 and 4A, the metal reflective layer 402 comprises an edge 402e formed on the second semiconductor layer 202 and covered by the first reflective structure 50. The first extending electrode 61 comprises a first extending electrode protrusion 610 protruding from the edge 402e of the metal reflective layer 402, partially or completely covering the first reflective structure outer opening 5011, and contacts the first semiconductor layer first surface 201t1 through the first reflective structure outer opening 5011 in the outer region 2011. The first extending electrode protrusion 610 comprises a first region 610a formed between the first reflective structure 50 and the second reflective structure 70, and a second region 610b directly contacting the exposed first semiconductor layer first surface 201t1 to form the first extending electrode first contact area 611. The first region 610a comprises a first extending electrode first width W1 larger than a first extending electrode with a second width W2 of the second region 610b, i.e., the first extending electrode first contact area 611.

As shown in FIG. 4A, the portion where the first reflective structure 50 and the second reflective structure 70 contact in the outer region 2011 comprises a total thickness gradually decreasing from the outer region 2011 to the inner region 2010. The portion where the first reflective structure 50 and the second reflective structure 70 contact in the outer region 2011 comprises a first thickness T1 and a second thickness T2, and the second thickness T2 closer to the first sidewall 21S is larger than the first thickness T1 away from the first sidewall 21S. In an embodiment of the application, the first thickness T1 is between 1 μm and 5 μm, and the second thickness T2 is between 2 μm and 10 μm. The first thickness T1 and the second thickness T2 are measured in a direction perpendicular to the upper surface of the first semiconductor layer 201.

As shown in FIG. 4B, the portion of the insulating layer 30 and the first reflective structure 50 contact on the semiconductor mesa 20m comprises a third thickness T3 and a fourth thickness T4, and the fourth thickness T4 closer to the second sidewall 22S is larger than the third thickness T3 away from the second sidewall 22S. In an embodiment of the application, the third thickness T3 is between 1 μm and 5 μm, and the fourth thickness T4 is between 2 μm and 10 μm. The thickness is measured in a direction perpendicular to the upper surface of the second semiconductor layer 202.

As shown in FIGS. 4A and 4B, the first reflective structure 50 comprises a first reflective portion 510 covering the first sidewall 21S, a second reflective portion 520 covering the second sidewall 22S, a first reflective bottom 530 formed on or contacting the first semiconductor layer first surface 201t1, and a first reflective top 540 formed on the contact electrode 40 or on the second semiconductor layer 202. In another embodiment, the first reflective top 540 is formed between the edge 402e of the metal reflective layer 402 and the second sidewall 22S. As shown in FIG. 3, the first reflective portion 510, the second reflective portion 520, the first reflective bottom 530, and the first reflective top 540 are connected in the top view of the light-emitting device 1 and form the first reflective structure outer opening 5011 to expose the first semiconductor layer first surface 201t1. As shown in FIG. 4A, each of the first reflective bottom 530 and the first reflective top 540 formed under the first extending electrode 61 comprises a first reflective structure thickness D1, and the first reflective structure thickness D1 is the thickness from an upper surface 530t of the first reflective bottom 530 to the first semiconductor layer first surface 201t1, or the thickness from an upper surface 540t of the first reflective top 540 to the second semiconductor layer first surface 202t or to an upper surface 30t of the insulating layer 30. The first reflective structure thickness D1 is between 1 μm and 3 μm. The first reflective portion 510 formed on the first sidewall 21S comprises a first portion thickness d11, wherein the first portion thickness d11 is measured from a side surface 510s of the first reflective portion 510 to the first sidewall 21S in a direction perpendicular to the first sidewall 21S. The second reflective portion 520 formed on the second sidewall 22S comprises a second portion thickness d12, wherein the second portion thickness d12 is measured from a side surface 520s of the second reflective portion 520 to the second sidewall 22S or the sidewall of the insulating layer 30 in the direction perpendicular to the second sidewall 22S. In the side view of the light-emitting device 1, each of the first reflective bottom 530 and the first reflective top 540 comprises an extending length projected on the first semiconductor layer first surface 201t1 or a virtual plane of the first semiconductor layer 201, which is larger than an extending length of the second reflective portion 520 projected on the first semiconductor layer first surface 201t1 or a virtual plane of the first semiconductor layer 201, and the first reflective structure thickness D1 is larger than the first portion thickness d11 and larger than the second portion thickness d12. In an embodiment, the thickness ratio (d11/D1) of the first portion thickness d11 to the first reflective structure thickness D1 or the thickness ratio (d12/D1) of the second portion thickness d12 to the first reflective structure thickness D1 is between 0.65-0.95, 0.75-0.9, or 0.8-0.85.

The second reflective structure 70 formed above the first extending electrode 61 comprises a second reflective structure first thickness D2 and the second reflective structure first thickness D2 is measured from an upper surface 70t of the second reflective structure 70 to an upper surface 61t of the first extending electrode 61. The second reflective structure 70 formed on the first sidewall 21S comprises a second reflective structure second thickness D2′, and the second reflective structure second thickness D2′ is measured from a side surface 70s of the second reflective structure 70 to the side surface 510s of the first reflective portion 510. The second reflective structure second thickness D2′ is between 1 μm and 3 μm. The second reflective structure second thickness D2′ is smaller than the second reflective structure first thickness D2, but the second reflective structure second thickness D2′ of the second reflective structure 70 formed on the first sidewall 21S is approximately the same as the first reflective structure thickness D1 to obtain the same effective reflectivity as the first reflective structure 50. In an embodiment, the thickness ratio (D2′/D2) of the second reflective structure second thickness D2′ to the second reflective structure first thickness D2 is between 0.65-0.95, 0.75-0.9, or 0.8-0.85. In an embodiment, the thickness ratio (D1/D2′) of the first reflective structure thickness D1 to the second reflective structure second thickness D2′ is between 0.8-1.2, 0.9-1.1, or 0.95-1.05. In an embodiment of the application, the first reflective structure 50 comprises the Distributed Bragg Reflector (DBR) structure. The optical thickness of the first reflective structure 50 for the main reflected light is designed by the axial light perpendicular to the first semiconductor layer first surface 201t1, the first semiconductor layer second surface 201t2, or the upper surface of the semiconductor mesa 20m. In an embodiment, the first reflective structure 50 can be formed by evaporation or sputtering, and the first reflective structure thickness D1 of the first reflective structure 50 formed above the first semiconductor layer first surface 201t1, the first semiconductor layer second surface 201t2 or the semiconductor mesa 20m is larger than the first portion thickness d11 on the first sidewall 21S and larger than the second portion thickness d12 on the second sidewall 22S. In an embodiment of the application, the second reflective structure 70 comprises the Distributed Bragg Reflector structure. The optical thickness of the second reflective structure 70 for the main reflected light is designed by the axial light perpendicular to the first sidewall 21S or the second sidewall 22S. In an embodiment, the second reflective structure 70 can be formed by evaporation or sputtering, and the second reflective structure second thickness D2′ is smaller than the second reflective structure first thickness D2. The first reflective structure 50 reflects the light emitted from the semiconductor stack 20 and perpendicularly to the upper surface 101 of the substrate 10, such as the light emitted from the first semiconductor layer first surface 201t1, the first semiconductor layer second surface 201t2 or the upper surface of the semiconductor mesa 20m. The second reflective structure 70 is then provided to supplement the reflection of the light that is not reflected by the first reflective structure 50, such as the light from the inclined surface of the semiconductor stack 20, for example the light emitted from the first sidewall 21S and the second sidewall 22S, thus the light extraction efficiency of the light-emitting device 1 is improved.

FIG. 4C illustrates a cross-sectional view of the line L-L′ in FIG. 3 in accordance with another embodiment of the present application. In an embodiment of the application, the light-emitting device 1 comprises an insulating reflective structure 34 formed between the contact electrode 40 and the semiconductor mesa 20m. The material of the insulating reflective structure 34 comprises SiO₂, SiN, SiOₓN_{y}, TiO₂, Si₃N₄, Al₂O₃, TiN, AlN, ZrO₂, TiAlN, TiSiN, HfO, TaO₂, Nb₂O₅, or MgF₂. The insulating reflective structure 34 comprises a multi-layer structure comprising insulating films with different refractive indices stacked alternately to form the Distributed Bragg Reflector (DBR). The multi-layer structure can be a structure comprising a first insulating film having a first refractive index and a second insulating film having a second refractive index alternately stacked, which are selected from the above materials but not limited to. In the embodiment, the insulating reflective structure 34 can be directly formed on the semiconductor mesa 20m without forming the insulating layer 30.

The insulating reflective structure 34 comprises the insulating reflective structure first thickness D3 and the insulating reflective structure second thickness D3′. In an embodiment, the thickness ratio (D3′/D3) of the insulating reflective structure second thickness D3′ to the insulating reflective structure first thickness D3 is between 0.65-0.95, 0.75-0.9, or 0.8-0.85. A portion of the insulating reflective structure 34 is formed under the contact electrode 40 and forms an omnidirectional reflector (ODR) with the metal reflective layer 402 to increase the reflectivity for the light emitted from the active layer 203 and improve the light extraction efficiency of the light-emitting device 1. The other portion of the insulating reflective structure 34 extends from the edge 402e of the metal reflective layer 402 to cover the area outside the semiconductor mesa 20m to reflect the light emitted from the active layer 203 and emitted outwards the second sidewall 22S and direct the light toward the substrate 10, thereby improving the light extraction efficiency of the light-emitting device 1. In an embodiment, the insulating reflective structure first thickness D3 is smaller than the first reflective structure thickness D1.

The first reflective structure 50 comprises a first bottom layer 501 and a first Distributed Bragg Reflector structure 503 formed on the first bottom layer 501. The first bottom layer 501 comprises an oxide or a nitride selected from the group consisting of silicon (Si), titanium (Ti), zirconium (Zr), niobium (Nb), tantalum (Ta), and aluminum (Al). The first Distributed Bragg Reflector structure 503 comprises two or more materials with different refractive indices alternately stacked, for example, by stacking SiO₂/TiO₂ or SiO₂/Nb₂O₅ layers. The first bottom layer 501 comprise the same material as a portion of the first Distributed Bragg Reflector structure 503. For example, when the first bottom layer 501 comprises SiO₂, the first Distributed Bragg Reflector structure 503 also comprises SiO₂. Although the first bottom layer 501 and a portion of the first Distributed Bragg Reflector structure 503 comprises the same material, the film qualities and the forming methods thereof of them are different, so the interface between the first bottom layer 501 and the first Distributed Bragg Reflector structure 503 can be distinguished visually (for example, TEM photos). When etching and removing portions of the first Distributed Bragg Reflector structure 503, in order to reduce physical damage for the first semiconductor layer first surface 201t1 or the first semiconductor layer second surface 201t2 (not shown), the multi-steps etching is provided to form the first reflective structure outer opening 5011. For example, a first etching step is provided to remove a portion of the first Distributed Bragg Reflector structure 503 to expose the first bottom layer 501, and then a second etching step is provided to remove the first bottom layer 501 to expose the first semiconductor layer first surface 201t1. When the first extending electrode 61 covers the first reflective structure outer opening 5011, the first extending electrode 61 comprises an end portion 61e with a gradually decreasing thickness formed on the first bottom layer 501.

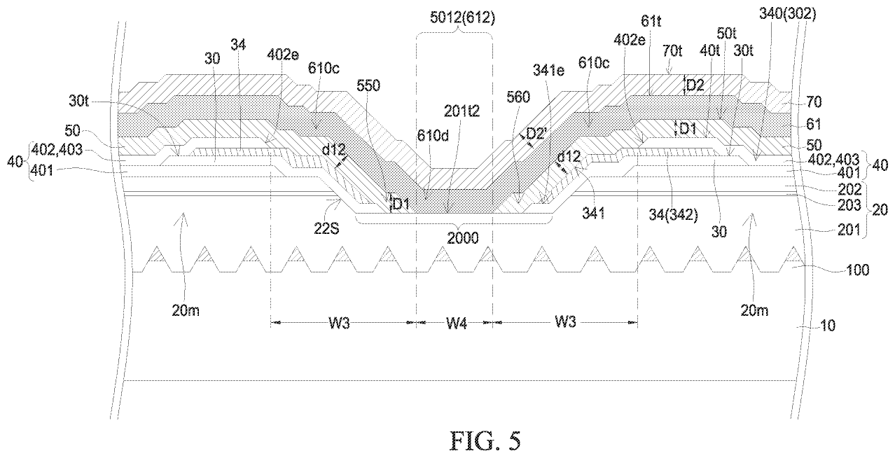

FIG. 5 illustrates a cross-sectional view along the line Y-Y′ of FIG. 1. As shown in FIG. 5, the via 2000 exposes the first semiconductor layer second surface 201t2 of the first semiconductor layer 201. The first reflective structure 50 covers the metal reflective layer 402, and comprises a third reflective portion 550 and a fourth reflective portion 560 protruding from the edge 402e of the metal reflective layer 402 and covering the first semiconductor layer second surface 201t2. The third reflective portion 550 and the fourth reflective portion 560 are connected in the top view of the light-emitting device 1 to form the first reflective structure inner opening 5012 to expose the first semiconductor layer second surface 201t2. The first extending electrode 61 covers the metal reflective layer 402 and extends from the edge 402e of the metal reflective layer 402 to cover the first reflective structure inner opening 5012, and contacts the first semiconductor layer second surface 201t2 through the first reflective structure inner opening 5012 to form the first extending electrode second contact area 612. The first extending electrode 61 comprises a third region 610c formed between the first reflective structure 50 and the second reflective structure 70, and a fourth region 610d directly contacting the first semiconductor layer second surface 201t2 to form the first extending electrode second contact area 612.

The first extending electrode second contact area 612 is surrounded by the third reflective portion 550 and the fourth reflective portion 560 of the first reflective structure 50. In an embodiment of the application, the third region 610c comprises a first extending electrode third width W3 larger than or equal to a first extending electrode fourth width W4 of the fourth region 610d, i.e., the first extending electrode second contact area 612. In the side view of the light-emitting device 1, the first extending electrode fourth width W4 is larger than, less than, or the same as the width of the third reflective portion 550 projected on the first semiconductor layer 201. However, the first extending electrode fourth width W4 is smaller than a total width of the third reflective portion 550 and the fourth reflective portion 560 projected on the first semiconductor layer 201. The first reflective structure 50 formed under the first extending electrode 61 comprises the first reflective structure thickness D1, the second reflective structure 70 formed above the first extending electrode 61 comprises the second reflective structure first thickness D2, and first reflective structure thickness D1 is smaller than the second reflective structure first thickness D2. The second reflective structure first thickness D2 is measured between the upper surface 70t of the second reflective structure 70 and the upper surface 61t of the first extending electrode 61. The first reflective structure thickness D1 is measured between the upper surface 50t of the first reflective structure 50 and the upper surface 40t of the contact electrode 40.

In an embodiment of the application, the insulating layer 30 is formed on the transparent conductive layer 401 and comprises one or a plurality of second insulating layer openings 302 to expose the transparent conductive layer 401.

In an embodiment of the application, the light-emitting device 1 comprises an insulating reflective structure 34 formed between the metal reflective layer 402 and the insulating layer 30. The insulating reflective structure 34 comprises one or a plurality of insulating reflective openings 340 corresponding to one or the plurality of the second insulating layer openings 302 and exposing the transparent conductive layer 401. In an embodiment of the application, when viewing from the top of the light-emitting device 1, the top view shape of the insulating reflective opening 340 comprises a circle, an ellipse, a semicircle, a triangle, a trapezoid, a square, or a rectangle. The insulating reflective opening 340 comprises an aperture or a width larger than that of the second insulating layer opening 302 to expose a portion of the upper surface 30t of the insulating layer 30. The material of the insulating reflective structure 34 comprises SiO₂, SiN, SiOₓN_{y}, TiO₂, Si₃N₄, Al₂O₃, TiN, AlN, ZrO₂, TiAlN, TiSiN, HfO, TaO₂, Nb₂O₅, or MgF₂. In an embodiment, the insulating reflective structure 34 comprises a multi-layer structure comprising the insulating films with different refractive indices alternately stacked, such as the Distributed Bragg Reflector (DBR). The multi-layer structure comprises the first insulating film having the first refractive index and the second insulating film having the second refractive index alternately stacked, which are selected from the above materials but not limited to. In another embodiment of the application, the insulating reflective structure 34 can be formed between the metal reflective layer 402 and the second semiconductor layer 203 by only extending the insulating reflective structure 34 on the semiconductor mesa 20m without additionally forming the insulating layer 30.

As shown in FIG. 5, the metal reflective layer 402 is formed on the insulating reflective structure 34 and contacts the transparent conductive layer 401 through the plurality of insulating reflective openings 340. In an embodiment, an adhesive layer (not shown) is formed between the insulating reflective structure 34 and the metal reflective layer 402 to improve the adhesion between the insulating reflective structure 34 and the metal reflective layer 402. The material of the adhesive layer comprises the same as that of the transparent conductive layer 401, such as indium tin oxide (ITO), zinc-doped indium tin oxide (ZITO), zinc indium oxide (ZIO), gallium indium oxide (GIO), zinc tin oxide (ZTO), fluorine-doped tin oxide (FTO), aluminum-doped zinc oxide (AZO), gallium-doped zinc oxide (GZO), or zinc-magnesium oxide (Zn₍₁₋ₓ₎MgₓG, (0≤x≤1)). The insulating reflective structure 34 and the metal reflective layer 402 form the omnidirectional reflector (ODR), which increases the reflectivity for the light emitted from the active layer 203 and improves the light extraction efficiency of the light-emitting device 1.

In an embodiment, the insulating reflective structure 34 comprises a first insulating reflective portion 341 covering the second sidewall 22S of the semiconductor mesa 20m and a second insulating reflective portion 342 formed on the semiconductor mesa 20m. Since the insulating layer 30 is formed between the first insulating reflective portion 341 and the semiconductor stack 20, the first insulating reflective portion 341 does not contact the first semiconductor layer first surface 201t1 (not shown) and/or the first semiconductor layer second surface 201t2, as shown in FIG. 5. However, the insulating layer 30 contacts the exposed first semiconductor layer first surface 201t1 (not shown) and/or the first semiconductor layer second surface 201t2, so that the first insulating reflective portion 341 and the second insulating reflective portion 342 are formed between the insulating layer 30 and the first reflective structure 50.

The first insulating reflective portion 341 formed on the second sidewall 22S comprises an end portion 341e comprising a thickness smaller than the thickness of the second insulating reflective portion 342 formed on the semiconductor mesa 20m. The end portion 341e of the first insulating reflective portion 341 comprises a thickness that gradually decreases outwards, and an oblique angle thereof is less than 45 degrees in the thickness direction.

Since the insulating reflective structure 34 extends from the edge 402e of the metal reflective layer 402 to cover the area outside the semiconductor mesa 20m, compared to the metal reflective layer 402, the insulating reflective structure 34 reflects the light emitted from the active layer 203 incident toward the second sidewalls 22S and directs the light outwards the substrate 10 more effectively, thereby improving the light extraction efficiency of the light-emitting device 1.

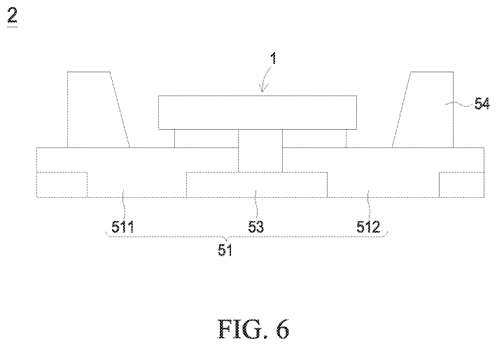

FIG. 6 is a schematic diagram of a light-emitting apparatus 2 according to an embodiment of the present application. The light-emitting device 1 in the foregoing embodiment is mounted on a first spacer 511 and a second spacer 512 of a package substrate 51 in the form of flip-chip. The first spacer 511 and the second spacer 512 are electrically insulated from each other by an insulating portion 53 comprising an insulating material. The main light-extraction surface of the flip chip is one side of the growth substrate opposite to the electrode-forming surface where the electrodes are formed on. For example, the substrate 10 of the light-emitting device 1 is the main light extraction surface of the light-emitting device 1. A reflective structure 54 can be arranged around the light emitting device 1 to increase the light extraction efficiency of the light-emitting apparatus 2.

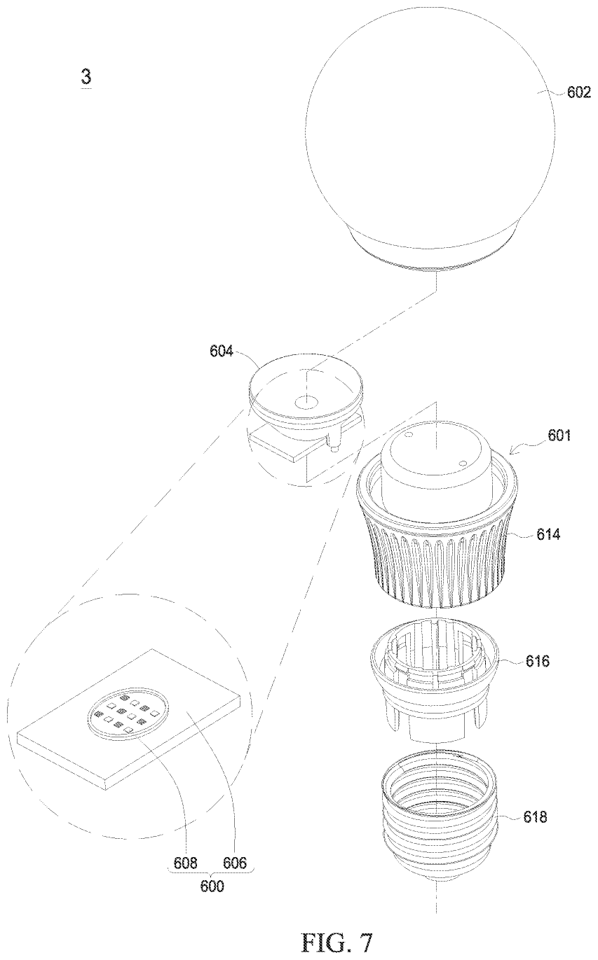

FIG. 7 is a schematic diagram of a light emitting apparatus 3 according to an embodiment of the present application. The light-emitting apparatus 3 can be a bulb comprising an envelope 602, a lens 604, a light-emitting module 600, a base 610, a heat sink 614, a connector 616, and an electrical connecting element 618. The light-emitting module 600 comprises a submount 606 and a plurality of light-emitting elements 608 on the submount 606, wherein the plurality of light-emitting elements 608 can be the light-emitting device 1 or the light-emitting apparatus 2 described in above embodiments.

The principle and the efficiency of the present application illustrated by the embodiments above are not the limitation of the application. Any person having ordinary skill in the art can modify or change the aforementioned embodiments. Therefore, the protection range of the rights in the application will be listed as the following claims.

What is claimed is:

1. A light-emitting device, comprising:
a semiconductor stack comprising a first semiconductor layer and a semiconductor mesa formed on the first semiconductor layer, wherein the first semiconductor layer comprises a first sidewall and a first semiconductor layer first surface surrounding the semiconductor mesa, the semiconductor mesa comprises a second semiconductor layer and a second sidewall, and the first semiconductor layer first surface is between the first sidewall and the second sidewall;
a first reflective structure comprising a first reflective portion covering the first sidewall and a second reflective portion covering the second sidewall, wherein the first reflective portion and the second reflective portion are connected to form a first reflective structure outer opening to expose the first semiconductor layer first surface in a top view of the light-emitting device;
a metal reflective layer comprising an edge formed on the second semiconductor layer and covered by the first reflective structure;
a first extending electrode covering the first reflective structure and contacting the first semiconductor layer first surface through the first reflective structure outer opening; and
a second reflective structure covering the first extending electrode and contacting the first reflective portion of the first reflective structure,
wherein the first extending electrode comprises a first extending electrode protrusion protruding outwards the edge of the metal reflective layer, the first extending electrode protrusion comprises a first region between the first reflective structure and the second reflective structure and a second region directly contacts the first semiconductor layer first surface, and the first region comprises a first extending electrode first width W1 larger than a first extending electrode second width W2 of the second region, and
wherein the first reflective structure formed under the first extending electrode comprises a first reflective structure thickness, the second reflective structure formed above the first extending electrode comprises a second reflective structure first thickness, and the first reflective structure thickness is smaller than the second reflective structure first thickness.

2. The light-emitting device according to claim 1, where the second reflective structure formed on the first sidewall comprises a second reflective structure second thickness approximately the same as the first reflective structure thickness.

3. The light-emitting device according to claim 2, wherein the second reflective structure second thickness is smaller than the second reflective structure first thickness.

4. The light-emitting device according to claim 1, further comprising an insulating layer formed under the first reflective structure, and the insulating layer comprises an insulating layer thickness thicker than a thickness of each sub-layer of the first reflective structure.

5. The light-emitting device according to claim 1, further comprising a via exposing a first semiconductor layer second surface of the first semiconductor layer, wherein the first reflective structure comprises a third reflective portion and a fourth reflective portion covering the first semiconductor layer second surface, the first extending electrode comprises a third region formed between the first reflective structure and the second reflective structure, and a fourth region directly contacting the first semiconductor layer second surface, and the third region comprises a first extending electrode third width larger than a first extending electrode fourth width of the fourth region.

6. The light-emitting device according to claim 5, wherein the first extending electrode fourth width is smaller than a total width of the third reflective portion and the fourth reflective portion projected on the first semiconductor layer.

7. The light-emitting device according to claim 6, wherein the first extending electrode fourth width is larger than a width of the third reflective portion projected on the first semiconductor layer.

8. The light-emitting device according to claim 5, further comprising an insulating reflective structure formed between the metal reflective layer and the second semiconductor layer, wherein the insulating reflective structure comprises a first insulating reflective portion covering the second sidewall, and the first insulating reflective portion does not contact the first semiconductor layer first surface.

9. The light-emitting device according to claim 8, wherein the first insulating reflective portion does not contact the first semiconductor layer second surface.

10. The light-emitting device according to claim 9, further comprising an insulating layer formed between the first insulating reflective portion and the first semiconductor layer second surface, wherein the insulating layer contacts the first semiconductor layer second surface.

11. The light-emitting device according to claim 8, further comprising an insulating layer formed between the first insulating reflective portion and the first semiconductor layer second surface, wherein the insulating layer comprises a first insulating layer portion contacting the first semiconductor layer, a second insulating layer portion contacting the second semiconductor layer, and a third insulating layer portion covering the second sidewall.

12. The light-emitting device according to claim 11, wherein the first insulating layer portion comprises a first length, the second insulating layer portion comprises a second length, and the second length is longer than the first length.

13. The light-emitting device according to claim 12, wherein the third insulating layer portion comprises a third length respectively shorter than the first length and the second length.

14. The light-emitting device according to claim 1, wherein the first extending electrode covers the first reflective structure outer opening.

15. The light-emitting device according to claim 14, wherein the first extending electrode comprises an end portion with a gradually decreasing thickness formed on the first reflective structure.

16. The light-emitting device according to claim 1, wherein the first extending electrode partially covers the first reflective structure outer opening, wherein the first extending electrode comprises an end portion formed in the first reflective structure outer opening.

17. The light-emitting device according to claim 1, wherein a top view shape of the first reflective structure outer opening comprises a semicircle, a triangle, a trapezoid, or a rectangle.

18. The light-emitting device according to claim 1, wherein first reflective structure comprises a first bottom layer and a first Distributed Bragg Reflector structure formed on the first bottom layer.

19. The light-emitting device according to claim 18, wherein the first bottom layer comprises the same material as a portion of the first Distributed Bragg Reflector structure.

20. The light-emitting device according to claim 19, wherein the first bottom layer comprises an oxide or a nitride selected from the group consisting of silicon (Si), titanium (Ti), zirconium (Zr), niobium (Nb), tantalum (Ta), and aluminum (Al).
